(19) United States
(12) Patent Application Publication
(10) Pub. No.: US 2025/0221038 A1
(43) Pub. Date: Jul. 3, 2025

(54) DISPLAY APPARATUS HAVING A THIN FILM TRANSISTOR AND A STORAGE CAPACITOR

(71) Applicant: LG Display Co., Ltd., Seoul (KR)

(72) Inventors: Chan Ho LEE, Paju-si (KR); Cheol Woo PARK, Paju-si (KR); Chan Soo PARK, Paju-si (KR); Gyu Sik WON, Paju-si (KR); Hyun Je BANG, Paju-si (KR)

(73) Assignee: LG Display Co., Ltd., Seoul (KR)

(21) Appl. No.: 18/978,732

(22) Filed: Dec. 12, 2024

(30) Foreign Application Priority Data
Dec. 28, 2023 (KR) 10-2023-0194881

(51) Int. Cl. H10D 86/40; H10D 86/60

(52) U.S. Cl. CPC H10D 86/481; H10D 86/441; H10D 86/60

(57) ABSTRACT

A display apparatus may include a display device electrically connected to the thin film transistor. The display device may emit light displaying a specific color. For example, the display device may include a light-emitting unit disposed between a first electrode and a second electrode. The thin film transistor may include a plurality of semiconductor patterns. The plurality of semiconductor patterns may be spaced apart in a first direction. The storage capacitor may include a sub-capacitor disposed between the semiconductor patterns spaced apart in the first direction. When the display apparatus is driven at high current, the reliability of the thin film transistor may be improved.

### CROSS-REFERENCE TO RELATED APPLICATIONS

This application claims the benefit of and priority to Korean Patent Application No. 10-2023-0194881, filed on Dec. 28, 2023, the entirety of which is incorporated herein by reference for all purposes as if fully set forth herein.

### BACKGROUND

### Technical Field

The present disclosure relates to a display apparatus, and particularly to, for example, without limitation, a display apparatus in which a driving circuit of each pixel area includes a thin film transistor and a storage capacitor.

### Discussion of the Related Art

Generally, a display apparatus provides an image to a user. For example, the display apparatus may include a display device, such as liquid crystal, mini light emitting diode (LED), micro LED and OLED. The display device may be controlled by a driving circuit. For example, in the display apparatus, a driving circuit electrically connected to the display device may be disposed in each pixel area.

The driving circuit may provide a driving current corresponding to a data signal to the display device according to a gate signal for one frame. For example, the driving circuit may include a thin film transistor and a storage capacitor. However, in the display apparatus, heat may be generated by an operation of the driving circuit. The heat generated by the operation of the driving circuit may be proportional to the drive current generated by the drive circuit. Thus, in the display apparatus, when the driving generated by the driving circuit is increased, the thin film transistor of the driving circuit may be deteriorated by the heat generated by the operation of the driving circuit. Therefore, in the display apparatus, when driven at high current, the reliability of the driving circuit may be reduced.

The description of the related art should not be assumed to be prior art merely because it is mentioned in or associated with this section. The description of the related art includes information that describes one or more aspects of the subject technology, and the description in this section does not limit the invention.

### SUMMARY

Accordingly, the present disclosure is directed to a display apparatus that substantially obviates one or more problems due to limitations and disadvantages of the related art.

In one or more aspects, an object of the present disclosure is to provide a display apparatus capable of stable high current driving.

In one or more aspects, another object of the present disclosure is to provide a display apparatus capable of minimizing or reducing the deterioration of the thin film transistor due to the operation of the driving circuit.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages of the present disclosure, as embodied and broadly described herein, in one or more aspects, there is provided a display apparatus comprising a driving circuit. The driving circuit is electrically connected to a display device. The driving circuit includes a thin film transistor and a storage capacitor. The thin film transistor includes a plurality of sub-transistors connected in parallel. Each of the sub-transistors includes a semiconductor pattern, a gate electrode, a drain electrode and a source electrode. The storage capacitor includes a sub-capacitor disposed between the semiconductor patterns, which are spaced apart in a first direction.

The semiconductor pattern of each sub-transistor may include a same material as the semiconductor pattern of an adjacent sub-transistor.

The semiconductor patterns may be disposed side by side in the first direction and a second direction. The second direction may be a direction perpendicular to the first direction. A distance between the semiconductor patterns adjacent in the second direction may be a same as a distance between the semiconductor patterns adjacent in the first direction.

The sub-capacitor may have a stacked structure of capacitor electrodes extending in the second direction.

The gate electrode, the drain electrode and the source electrode of each sub-transistor may extend in the second direction. The gate electrode, the drain electrode and the source electrode of each sub-transistor may be spaced apart from the gate electrode, the drain electrode and the source electrode of the sub-transistor adjacent in the first direction.

The drain electrode or the source electrode of each sub-transistor may include a same material as the gate electrode of the corresponding sub-transistor.

The thin film transistor may include a gate connection line, a drain connection line and a source connection line. The gate connection line, the drain connection line and the source connection line may extend in the first direction. The gate electrode of each sub-transistor may be electrically connected to the gate connection line. The drain electrode of each sub-transistor may be electrically connected to the drain connection line. The source electrode of each sub-transistor may be electrically connected to the source connection line.

The driving circuit and the display device may be supported by a device substrate. A light-blocking pattern may be disposed between the device substrate and the semiconductor pattern of each sub-transistor. The gate connection line may be disposed on a same layer as the light-blocking patterns. The drain connection line and the source connection line may be disposed on a different layer than the gate connection line.

The semiconductor pattern of each sub-transistor may be disposed between the drain connection line and the source connection line. The gate connection line may extend along between the drain connection line and the semiconductor patterns and between the semiconductor patterns and the source connection line. The sub-capacitor may have a stacked structure of a first capacitor electrode and a second capacitor electrode. The first capacitor electrode may be electrically connected to the gate connection line. The second capacitor electrode may be electrically connected to the source connection line.

The display device may include a light-emitting unit disposed between a first electrode and a second electrode. The light-emitting unit may include at least one emission material layer.

In another example embodiment, there is provided a display apparatus comprising a device substrate. A first thin film transistor and a second thin film transistor are disposed in a pixel area of the device substrate. The second thin film transistor includes a gate connection line, a drain connection line, a source connection line, and semiconductor patterns. The first thin film transistor is electrically connected to the gate connection line of the second thin film transistor. The source connection line of the second thin film transistor is electrically connected to a display device. The semiconductor patterns are spaced apart in a first direction. A storage capacitor is disposed between the gate connection line and the source connection line of the second thin film transistor. The storage capacitor includes a sub-capacitor. The sub-capacitor is disposed between the semiconductor patterns, which are spaced apart in the first direction.

The semiconductor patterns may be spaced apart in a second direction. The second direction may be a direction perpendicular to the first direction. Each of the semiconductor patterns may be arranged to be staggered in the second direction with the semiconductor pattern adjacent in the first direction.

The second thin film transistor may include a plurality of gate electrodes, a plurality of drain electrodes and a plurality of source electrodes. The plurality of gate electrodes may be electrically connected to the gate connection line. The plurality of drain electrodes may be electrically connected to the drain connection line. The plurality of source electrodes may be electrically connected to the source connection line. Each of the gate electrodes may overlap a channel region of at least one of the semiconductor patterns. Each of the drain electrodes may be electrically connected to a drain region of at least one of the semiconductor patterns. Each of the source electrodes may be electrically connected to a source region of at least one of the semiconductor patterns.

The drain electrodes may be disposed on a same layer as the drain connection line. The source electrodes may be disposed on a same layer as the source connection line. The gate electrodes may be disposed on a different layer than the gate connection line.

The source connection line may be disposed on a different layer than the gate connection line. The sub-capacitor may have a stacked structure of a first capacitor electrode and a second capacitor electrode. The first capacitor electrode may be disposed on a same layer as the gate connection line. The second capacitor electrode may be disposed on a same layer as the source connection line.

Other apparatuses, methods, features and advantages will be, or will become, apparent to one with skill in the art upon examination of the drawings and detailed description herein. It is intended that all such apparatuses, methods, features and advantages be included within this description, be within the scope of the present disclosure, and be protected by the following claims. Nothing in this section should be taken as a limitation on the claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure. In the drawings:

FIG. 1 is a view schematically showing a display apparatus according to an example embodiment of the present disclosure;

FIG. 2 is a view showing a circuit of a pixel area in the display apparatus according to the example embodiment of the present disclosure;

FIG. 3 is a view showing a plane of a second thin film transistor and a storage capacitor disposed in the pixel area in the display apparatus according to the example embodiment of the present disclosure;

FIG. 4 is an example of an enlarged view of K region in FIG. 3;

FIG. 5 is an example of a view taken along I-I′ and II-II′ of FIG. 4;

FIG. 6 is an example of a view taken along III-III′ of FIG. 4;

FIG. 7 is an example of a view taken along IV-IV′ of FIG. 4;

FIG. 8 is an example of a view taken along V-V′ of FIG. 4; and

FIGS. 9 to 12 are views showing the display apparatus according to another example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Hereinafter, details related to the above objects, technical configurations, and operational effects of the example embodiments of the present disclosure will be clearly understood by the following detailed description with reference to the drawings, which illustrate some embodiments of the present disclosure. Here, the example embodiments of the present disclosure are provided in order to allow the technical sprit of the present disclosure to be satisfactorily transferred to those skilled in the art, and thus the present disclosure may be embodied in other forms and is not limited to the example embodiments described below.

In addition, the same or extremely similar elements may be designated by the same reference numerals throughout the specification and in the drawings, the lengths and thickness of layers and regions may be exaggerated for convenience. It will be understood that, when a first element is referred to as being “on” a second element, although the first element may be disposed on the second element so as to come into contact with the second element, a third element may be interposed between the first element and the second element.

Here, terms such as, for example, “first” and “second” may be used to distinguish any one element with another element. However, the first element and the second element may be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises,” “has,” “contains”, “constitutes,” “made of,” “formed of,” “includes” and the like specify the presence of stated features, integers, steps, operations, elements, components, and/or combinations thereof, but do not preclude the presence or addition of one or more other features, integers, steps, operations, elements, components, and/or combinations.

And, unless “directly” is used, the terms “connected” and “coupled” may include that two components are “connected” or “coupled” through one or more other components located between the two components.

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, regions, components, sections, members, parts, regions, areas, portions, and/or the like) are described using any of the terms such as “on,” “on a top of,” “upon,” “on top of,” “over,” “under,” “above,” “upper,” “below,” “lower,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, regions, components, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

For the expression that an element (e.g., layer, film, region, component, section, member, part, region, area, portion, or the like) is “connected,” “coupled,” “attached,” “adhered,” “linked,” or the like to another element, the element can not only be directly connected, coupled, attached, adhered, linked, or the like to another element, but also be indirectly connected, coupled, attached, adhered, linked, or the like to another element with one or more intervening elements disposed or interposed between the elements, unless otherwise specified.

For the expression that an element (e.g., layer, film, region, component, section, member, part, region, area, portion, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, section, member, part, region, area, portion, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

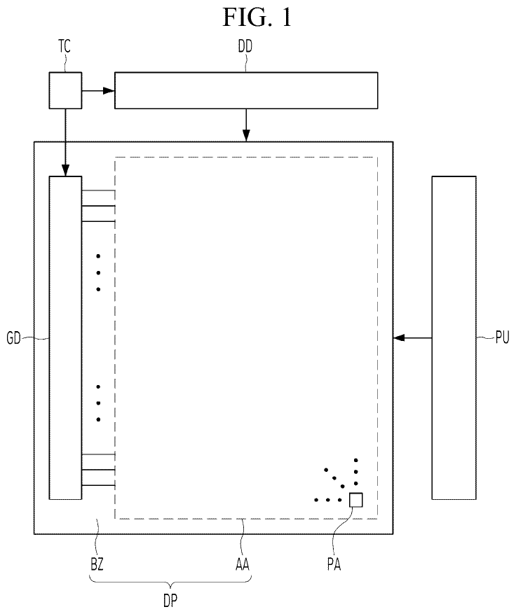

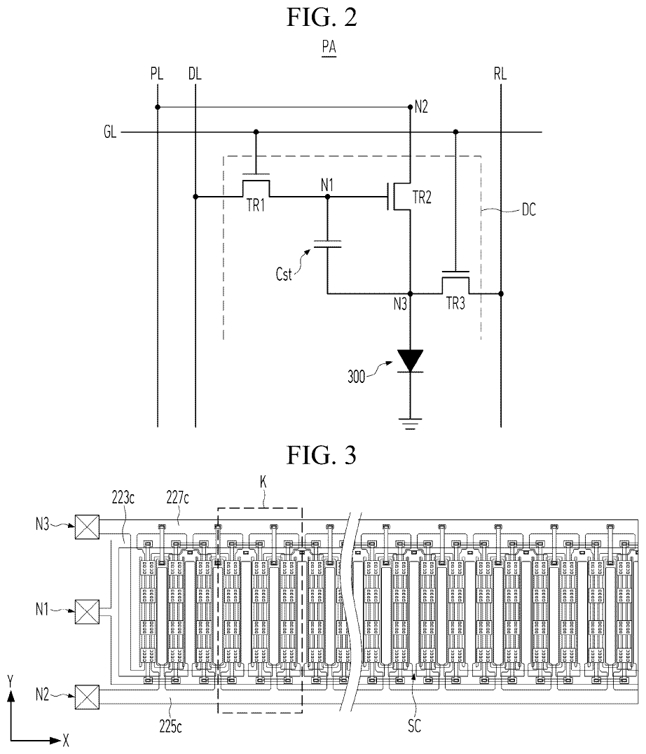

FIG. 1 is a view schematically showing a display apparatus according to an example embodiment of the present disclosure. FIG. 2 is a view showing a circuit of a pixel area in the display apparatus according to the example embodiment of the present disclosure.

Referring to FIGS. 1 and 2, the display apparatus according to the example embodiment of the present disclosure may include a display panel DP. The display panel DP may generate an image provided to a user. For example, the display panel DP may include a plurality of pixel areas PA. Each of the pixel areas PA may be defined by signal wirings GL, DL, PL and RL. For example, each of the pixel areas PA may be surrounded by the signal wirings GL, DL, PL and RL. The signal wirings GL, DL, PL and RL may apply various signals to each pixel area PA. For example, the signal wirings GL, DL, PL and RL may include gate lines GL sequentially applying a gate signal, data lines DL applying a data signal, power voltage supply lines PL supplying a power voltage, and reference voltage supply lines RL supplying a reference voltage.

The gate lines GL may be electrically connected to the gate driver GD. The data lines DL may be electrically connected to the data driver DD. The power voltage supply lines PL and the reference voltage supply lines RL may be electrically connected to the power unit PU. The gate driver GD and the data driver DD may be controlled by a timing controller TC. For example, the gate driver GD may receive clock signals, reset signals and a start signal from the timing controller TC, and the data driver DD may receive digital video data and a source timing signal from the timing controller TC.

The display panel DP may include an active area AA in which the pixel areas PA are disposed, and a bezel area BZ disposed outside the active area AA. The bezel area BZ may be disposed outside the pixel areas PA. For example, the active area AA may be surrounded by the bezel area BZ. The gate driver GD, the data driver DD, the power unit PU and the timing controller TC may be disposed outside the active area AA. For example, each of the signal wirings GL, DL, PL and RL may include a portion disposed on the bezel area BZ.

At least one of the gate driver GD, the data driver DD, the power unit PU and the timing controller TC may be disposed on the bezel area BZ. For example, the display apparatus according to the example embodiment of the present disclosure may be a Gate in Panel (GIP) type display apparatus in which the gate driver GD is formed on the bezel area BZ.

Each of the pixel areas PA may realize a specific color by the signal wirings GL, DL, PL and RL. For example, a driving circuit DC electrically connected to a display device 300 may be disposed in each pixel area PA. The driving circuit DC of each pixel area PA may be electrically connected to the signal wirings GL, DL, PL and RL. For example, the driving circuit DC of each pixel area PA may be electrically connected to one of the gate lines GL, one of the data lines DL, one of the power voltage supply lines PL and one of the reference voltage supply lines RL. The driving circuit DC of each pixel area PA may supply a driving current corresponding to the data signal to the display device 300 of the corresponding pixel area PA according to the gate signal for one frame. For example, the driving circuit DC of each pixel area PA may include a first thin film transistor TR1, a second thin film transistor TR2, a third thin film transistor TR3 and a storage capacitor Cst.

The first thin film transistor TR1 may transmit the data signal to the second thin film transistor TR2 according to the gate signal. For example, the first thin film transistor TR1 may function as a switching thin film transistor. The first thin film transistor TR1 may include a first semiconductor pattern, a first gate electrode, a first drain electrode and a first source electrode. For example, the first gate electrode may be electrically connected to the corresponding gate line GL, and the first drain electrode may be electrically connected to the corresponding date line DL.

The first semiconductor pattern may include a semiconductor material. For example, the first semiconductor pattern may include amorphous silicon (a-Si), polycrystalline silicon (poly-Si) or an oxide semiconductor, such as IGZO. The first semiconductor pattern may include a first drain region, a first channel region and a first source region. The first channel region may be disposed between the first drain region and the first source region. A resistance of the first drain region and a resistance of the first source region may be a smaller that a resistance of the first channel region. For example, the first drain region and the first source region may include a conductive region of an oxide semiconductor. The first channel region may be a region of an oxide semiconductor, which is not conductorized.

The first gate electrode may be disposed on a portion of the first semiconductor pattern. For example, the first gate electrode may overlap the first channel region of the first semiconductor pattern. The first drain region and the first source region of the first semiconductor pattern may be disposed outside the first gate electrode. The first gate electrode may include a conductive material. For example, the first gate electrode may include a metal, such as aluminum (Al), chrome (Cr), copper (Cu), molybdenum (Mo), titanium (Ti) and tungsten (W). The first gate electrode may be spaced apart from the first semiconductor pattern. The first gate electrode may be insulated from the first semiconductor pattern. For example, the first drain region of the first semiconductor pattern may be electrically connected to the first source region of the first semiconductor pattern according to a signal applied to the first gate electrode.

The first drain electrode may include a conductive material. For example, the first drain electrode may include a metal, such as aluminum (Al), chrome (Cr), copper (Cu), molybdenum (Mo), titanium (Ti) and tungsten (W). The first drain electrode may include a different material from the first gate electrode. For example, the first drain electrode may be disposed on a different layer than the first gate electrode. The first drain electrode may be electrically connected to the first drain region of the first semiconductor pattern. The first drain electrode may be insulated from the first gate electrode.

The first source electrode may include a conductive material. For example, the first source electrode may include a metal, such as aluminum (Al), chrome (Cr), copper (Cu), molybdenum (Mo), titanium (Ti) and tungsten (W). The first source electrode may include a different material from the first gate electrode. The first source electrode may be disposed on a different layer than the first gate electrode. For example, the first source electrode may be disposed on a same layer as the first drain electrode. The first source electrode may include a same material as the first drain electrode. The first source electrode may be formed by a same process as the first drain electrode. For example, the first source electrode may be formed simultaneously with the first drain electrode. The first source electrode may be electrically connected to the first source region of the first semiconductor pattern. The first source electrode may be insulated from the first gate electrode. The first source electrode may be spaced apart from the first drain electrode.

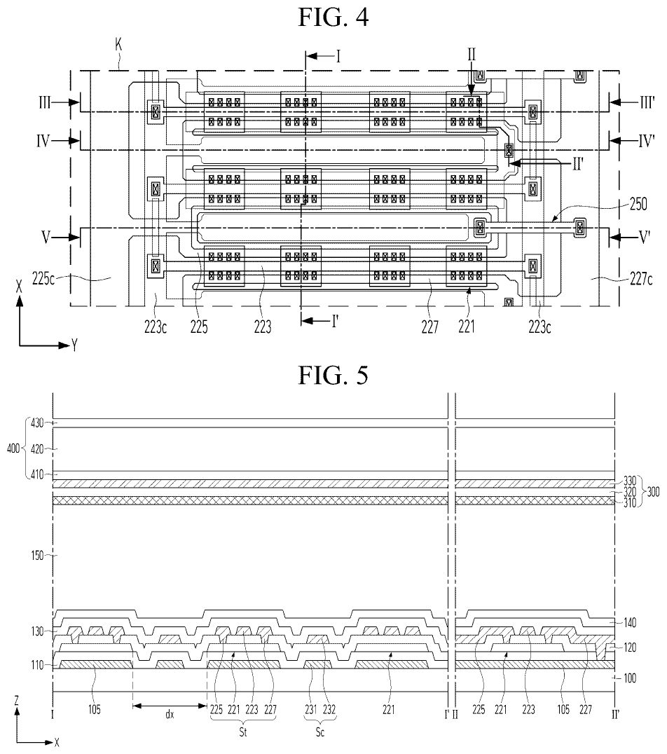

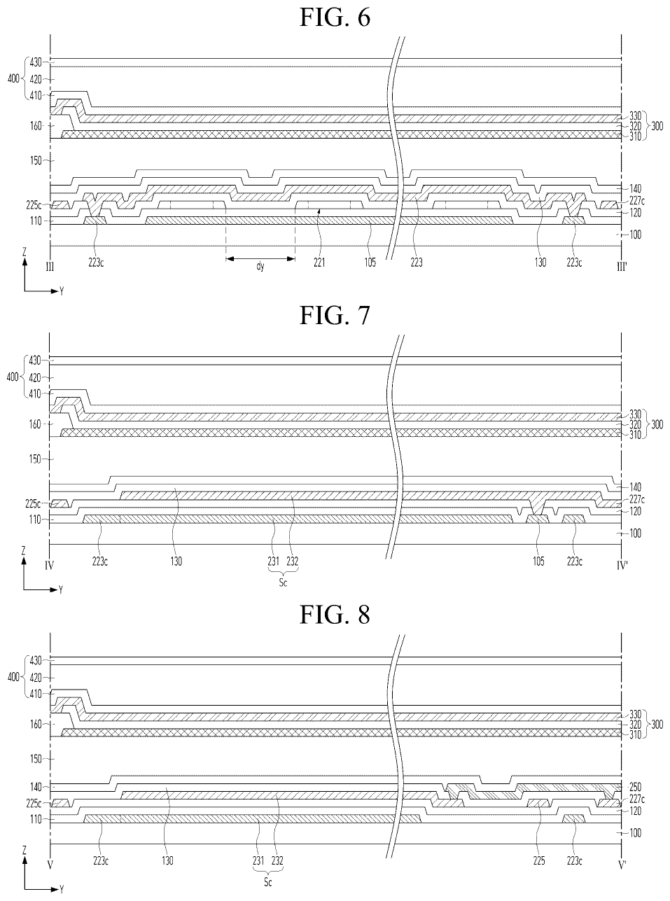

FIG. 3 is a view showing a plane of a second thin film transistor and a storage capacitor disposed in the pixel area in the display apparatus according to the example embodiment of the present disclosure. FIG. 4 is an example of an enlarged view of K region in FIG. 3. FIG. 5 is an example of a view taken along I-I′ and II-II′ of FIG. 4. FIG. 6 is an example of a view taken along III-III′ of FIG. 4. FIG. 7 is an example of a view taken along IV-IV′ of FIG. 4. FIG. 8 is an example of a view taken along V-V′ of FIG. 4.

Referring to FIGS. 2 to 8, the second thin film transistor TR2 may generate the driving current corresponding to the data signal. For example, the second thin film transistor TR2 may function as a driving thin film transistor. The second thin film transistor TR2 may include a plurality of second semiconductor patterns 221, a plurality of second gate electrodes 223, a gate connection line 223c, a plurality of second drain electrodes 225, a drain connection line 225c, a plurality of second source electrodes 227 and a source connection line 227c.

Each of the second semiconductor patterns 221 may include a semiconductor material. For example, each of the second semiconductor patterns 221 may include amorphous silicon (a-Si), polycrystalline silicon (poly-Si) or an oxide semiconductor, such as IGZO. Each of the second semiconductor patterns 221 may include a same material as adjacent second semiconductor pattern 221. Each of the second semiconductor patterns 221 may be disposed on a same layer as adjacent second semiconductor pattern 221. Each of the second semiconductor patterns 221 may be formed by a same process as adjacent second semiconductor pattern 221. For example, each of the second semiconductor patterns 221 may be formed simultaneously with adjacent second semiconductor pattern 221. The second semiconductor patterns 221 may be disposed side by side in a first direction X and a second direction Y perpendicular to the first direction X. For example, each of the second semiconductor patterns 221 may be spaced apart from the second semiconductor pattern 221 adjacent in the first direction X and the second semiconductor pattern 221 adjacent in the second direction Y. A distance dy between the second semiconductor patterns 221 adjacent in the second direction Y may be a same as a distance dx between the second semiconductor pattern 221 adjacent in the first direction X.

Each of the second semiconductor patterns 221 may include a second drain region, a second channel region and a second source region. The second channel region may be disposed between the second drain region and the second source region. The second drain region and the second source region may have a resistance smaller than the second channel region. For example, the second drain region and the second source region may include a conductive region of an oxide semiconductor. The second channel region may be a region of an oxide semiconductor, which is not conductorized.

Each of the second gate electrodes 223 may be disposed on a portion of at least one of the second semiconductor patterns 221. For example, each of the second gate electrodes 223 may overlap the second channel region of at least one of the second semiconductor patterns 221. The second drain region and the second source region of each semiconductor pattern 221 may be disposed outside the second gate electrodes 223. Each of the second gate electrodes 223 may extend in the second direction Y. For example, the second channel regions of the second semiconductor patterns 221 disposed side by side in the second direction Y may overlap one of the second gate electrodes 223. Each of the second gate electrodes 223 may be spaced apart from the second gate electrode 223 adjacent in the first direction X.

Each of the second gate electrodes 223 may include a conductive material. For example, each of the second gate electrodes 223 may include a metal, such as aluminum (Al), chrome (Cr), copper (Cu), molybdenum (Mo), titanium (Ti) and tungsten (W). Each of the second gate electrodes 223 may be spaced apart from the second semiconductor patterns 221. Each of the second gate electrodes 223 may be insulated from the second semiconductor patterns 221. For example, the second channel region of each second semiconductor pattern 221 may have an electrical conductivity corresponding to a voltage applied to one of the second gate electrodes 223.

The gate connection line 223c may be electrically connected to the first thin film transistor TR1 through a first node N1. For example, the first node N1 may be electrically connected to the first source electrode and the gate connection line 223c. The gate connection line 223c may include a conductive material. For example, the gate connection line 223c may include a metal, such as aluminum (Al), chrome (Cr), copper (Cu), molybdenum (Mo), titanium (Ti) and tungsten (W).

Each of the second gate electrodes 223 may be electrically connected to the gate connection line 223c. For example, the date signal transmitted through the first source electrode of the first thin film transistor TR1 may be supplied simultaneously to the second gate electrodes 223 through the gate connection line 223c. The gate connection line 223c may extend in the first direction X. The gate connection line 223c may include a different material from the second gate electrodes 223. For example, the gate connection line 223c may be disposed on a different layer than the second gate electrodes 223. Each of the second gate electrodes 223 may include a first end electrically connected to the gate connection line 223c.

Each of the second drain electrodes 225 may include a conductive material. For example, each of the second drain electrodes 225 may include a metal, such as aluminum (Al), chrome (Cr), copper (Cu), molybdenum (Mo), titanium (Ti) and tungsten (W). The second drain electrodes 225 may include a same material as the second gate electrodes 223. The second drain electrodes 225 may be disposed on a same layer as the second gate electrodes 223. The second drain electrodes 225 may be formed by a same process as the second gate electrodes 223. For example, the second drain electrodes 225 may be formed simultaneously with the second gate electrodes 223.

Each of the second drain electrodes 225 may be electrically connected to the second drain region of at least one of the second semiconductor patterns 221. Each of the second drain electrodes 225 may be spaced apart from the second gate electrodes 223. Each of the second drain electrodes 225 may be insulated from the second gate electrodes 223. Each of the second drain electrodes 225 may extend in the second direction Y. For example, the second drain regions of the second semiconductor patterns 221 disposed side by side in the second direction Y may be electrically connected to one of the second drain electrodes 225. Each of the second drain electrodes 225 may be spaced apart from the second drain electrode 225 adjacent in the first direction X.

The drain connection line 225c may be electrically connected to the corresponding power voltage supply line PL through a second node N2. The drain connection line 225c may include a conductive material. For example, the drain connection line 225c may include a metal, such as aluminum (Al), chrome (Cr), copper (Cu), molybdenum (Mo), titanium (Ti) and tungsten (W).

Each of the second drain electrodes 225 may be electrically connected to the drain connection line 225c. For example, the power voltage supplied through the second node N2 may be supplied simultaneously to the second drain electrodes 225 through the drain connection line 225c. The drain connection line 225c may extend in the first direction X. The drain connection line 225c may include a different material from the gate connection line 223c. The drain connection line 225c may be disposed on a different layer than the gate connection line 223c. For example, the drain connection line 225c may be disposed on a same layer as the second drain electrodes 225. The drain connection line 225c may include a same material as the second drain electrodes 225. The drain connection line 225c may be formed by a same process as the second drain electrodes 225. For example, the drain connection line 225c may be formed simultaneously with the second drain electrodes 225. Each of the second drain electrodes 225 may be in direct contact with the drain connection line 225c. Each of the second gate electrodes 223 may be spaced apart from the drain connection line 225c. Each of the second gate electrodes 223 may be insulated from the drain connection line 225c.

Each of the second source electrodes 227 may include a conductive material. For example, each of the second source electrodes 227 may include a metal, such as aluminum (Al), chrome (Cr), copper (Cu), molybdenum (Mo), titanium (Ti) and tungsten (W). The second source electrodes 227 may include a same material as the second drain electrodes 225. The second source electrodes 227 may be disposed on a same layer as the second drain electrodes 225. The second source electrodes 227 may be formed by a same process as the second drain electrodes 225. For example, the second source electrodes 227 may be formed simultaneously with the second drain electrodes 225.

Each of the second source electrodes 227 may be electrically connected to the second source region of at least one of the second semiconductor patterns 221. Each of the second source electrodes 227 may be insulated from the second gate electrodes 223. Each of the second source electrodes 227 may be spaced apart from the second gate electrodes 223 and the second drain electrodes 225. Each of the second source electrodes 227 may extend in the second direction Y. For example, the second source regions of the second semiconductor patterns 221 disposed side by side in the second direction Y may be electrically connected to one of the second source electrodes 227. Each of the second source electrodes 227 may be spaced apart from the second source electrode 227 adjacent in the first direction X.

Each of the second semiconductor patterns 221 may constitute a sub-transistor St with the second gate electrode 223 overlapping with the second channel region of the corresponding second semiconductor pattern 221, the second drain electrode 225 electrically connected to the second drain region of the corresponding second semiconductor pattern 221, and the second source electrode 227 electrically connected to the second source region of the corresponding second semiconductor pattern 221. For example, the second thin film transistor TR2 may include a plurality of sub-transistors St. The sub-transistors St may be disposed side by side in the first direction X and the second direction Y. For example, each of the sub-transistors St may include the second gate electrode 223 different from the sub-transistor St adjacent in the first direction X. The sub-transistors St adjacent in the second direction Y may include a same second drain electrode 225 and a same second source electrode 227.

The source connection line 227c may be electrically connected to a third node N3. The source connection line 227c may include a conductive material. For example, the source connection line 227c may include a metal, such as aluminum (Al), chrome (Cr), copper (Cu), molybdenum (Mo), titanium (Ti) and tungsten (W).

Each of the second source electrodes 227 may be electrically connected to the source connection line 227c. For example, the source connection line 227c may extend in the first direction X. The source connection line 227c may include a different material from the gate connection line 223c. The source connection line 227c may be disposed on a different layer than the gate connection line 223c. For example, the source connection line 227c may be disposed on a same layer as the second source electrodes 227. The source connection line 227c may include a same material as the second source electrodes 227. The source connection line 227c may be formed by a same process as the second source electrodes 227. For example, the source connection line 227c may be formed simultaneously with the second source electrodes 227. Each of the second source electrodes 227 may be in direct contact with the source connection line 227c. Each of the second gate electrodes 223 and each of the second drain electrodes 225 may be spaced apart from the source connection line 227c. Each of the second gate electrodes 223 and each of the second drain electrodes 225 may be insulated from the source connection line 227c. Thus, in the display apparatus according to the example embodiment of the present disclosure, the plurality of sub-transistors St may function as a single second thin film transistor TR2. For example, in the display apparatus according to the example embodiment of the present disclosure, the second thin film transistor TR2 of each pixel area PA may include a plurality of sub-transistors St connected in parallel by the gate connection line 223c, the drain connection line 225c and the source connection line 227c of the corresponding pixel area PA.

The second semiconductor patterns 221 may be disposed between the drain connection line 225c and the source connection line 227c. For example, the gate connection line 223c may extend between the drain connection line 225c and the second semiconductor patterns 221 and between the second semiconductor patterns 221 and the source connection line 227c. In the display apparatus according to the example embodiment of the present disclosure, when one of the sub-transistors is not normally driven, one of the second gate electrodes 223, one of the second drain electrodes 225 and one of the second source electrodes 227 may be cut, so that the sub-transistors St adjacent to the corresponding sub-transistor St in the second direction Y may not be driven. Thus, in the display apparatus according to the example embodiment of the present disclosure, the driving current may be generated by the second thin film transistor TR2, even if a defect occurs in some of the sub-transistors St due to a conductive foreign material or an electrostatic short. That is, in the display apparatus according to the example embodiment of the present disclosure, a repair of the second thin film transistor TR2 may be possible. Therefore, in the display apparatus according to the example embodiment of the present disclosure, the reliability of the second thin film transistor TR2 may be improved.

The third thin film transistor TR3 may transmit the reference voltage to the storage capacitor Cst according to the gate signal. For example, the third thin film transistor TR3 may function as a switching thin film transistor. The third thin film transistor TR3 may have a same structure as the first thin film transistor TR1. For example, the third thin film transistor TR3 may include a third semiconductor pattern, a third gate electrode, a third drain electrode and a third source electrode. The third gate electrode may be electrically connected to the corresponding gate lines GL, the third drain electrode may be electrically connected to the corresponding reference voltage supply lines RL, and the third source electrode may be electrically connected to the third node N3.

The third semiconductor pattern may include a semiconductor material. For example, the third semiconductor pattern may include amorphous silicon (a-Si), polycrystalline silicon (poly-Si) or an oxide semiconductor, such as IGZO. The third semiconductor pattern may include a third drain region, a third channel region and a third source region. The third channel region may be disposed between the third drain region and the third source region. A resistance of the third drain region and a resistance of the third source region may be a smaller that a resistance of the third channel region. For example, the third drain region and the third source region may include a conductive region of an oxide semiconductor. The third channel region may be a region of an oxide semiconductor, which is not conductorized.

The third semiconductor pattern may include a same material as the first semiconductor pattern. The third semiconductor pattern may be disposed on a same layer as the first semiconductor pattern. The third semiconductor pattern may be formed by a same process as the first semiconductor pattern. For example, the third semiconductor pattern may be formed simultaneously with the first semiconductor pattern.

The third gate electrode may be disposed on a portion of the third semiconductor pattern. For example, the third gate electrode may overlap the third channel region of the third semiconductor pattern. The third drain region and the third source region of the third semiconductor pattern may be disposed outside the third gate electrode. The third gate electrode may include a conductive material. For example, the third gate electrode may include a metal, such as aluminum (Al), chrome (Cr), copper (Cu), molybdenum (Mo), titanium (Ti) and tungsten (W). The third gate electrode may be spaced apart from the third semiconductor pattern. The third gate electrode may be insulated from the third semiconductor pattern. For example, the third drain region of the third semiconductor pattern may be electrically connected to the third source region of the third semiconductor pattern according to a signal applied to the third gate electrode.

The third gate electrode may include a same material as the first gate electrode. The third gate electrode may be disposed on a same layer as the first gate electrode. The third gate electrode may be formed by a same process as the first gate electrode. For example, the third gate electrode may be formed simultaneously with the first gate electrode.

The third drain electrode may include a conductive material. For example, the third drain electrode may include a metal, such as aluminum (Al), chrome (Cr), copper (Cu), molybdenum (Mo), titanium (Ti) and tungsten (W). The third drain electrode may include a different material from the third gate electrode. For example, the third drain electrode may be disposed on a different layer than the third gate electrode. The third drain electrode may be electrically connected to the third drain region of the third semiconductor pattern. The third drain electrode may be insulated from the third gate electrode.

The third drain electrode may include a same material as the first drain electrode. The third drain electrode may be disposed on a same layer as the first drain electrode. The third drain electrode may be formed by a same process as the first drain electrode. For example, the third drain electrode may be formed simultaneously with the first drain electrode.

The third source electrode may include a conductive material. For example, the third source electrode may include a metal, such as aluminum (Al), chrome (Cr), copper (Cu), molybdenum (Mo), titanium (Ti) and tungsten (W). The third source electrode may include a different material from the third gate electrode. The third source electrode may be disposed on a different layer than the third gate electrode. For example, the third source electrode may be disposed on a same layer as the third drain electrode. The third source electrode may include a same material as the third drain electrode. The third source electrode may be formed by a same process as the third drain electrode. For example, the third source electrode may be formed simultaneously with the third drain electrode. The third source electrode may be electrically connected to the third source region of the third semiconductor pattern. The third source electrode may be insulated from the third gate electrode. The third source electrode may be spaced apart from the third drain electrode.

The storage capacitor Cst may maintain a signal applied to the first node N1 for one frame. For example, the storage capacitor Cst may be electrically connected to the first node N1 and the third node N3. The storage capacitor Cst may be disposed between the drain connection line 225c and the source connection line 227c. For example, the storage capacitor Cst may include a plurality of sub-capacitors Sc disposed between the second semiconductor patterns 221, which are spaced apart in the first direction X. Thus, in the display apparatus according to the example embodiment of the present disclosure, a gap between sub-transistors St adjacent in the first direction X may be sufficiently secured, without increasing the size of each pixel area PA. That is, in the display apparatus according to the example embodiment of the present disclosure, the heat generated by the operation of the driving circuit DC in each pixel area PA may be rapidly dissipated through a space between the second semiconductor patterns 221 spaced apart in the first direction X. Therefore, in the display apparatus according to the example embodiment of the present disclosure, the deterioration of the second thin film transistor TR2 due to the operation of the driving circuit DC in each pixel area PA may be reduced or minimized. And, in the display apparatus according to the example embodiment of the present disclosure, the high-current driving generating relatively much heat, may be operated stably.

Each of the sub-capacitors Sc may have a stacked structure of capacitor electrodes 231 and 232. For example, each of the sub-capacitors Sc may include a first capacitor electrode 231 electrically connected to the gate connection line 223c and a second capacitor electrode 232 electrically connected to the source connection line 227c. The first capacitor electrode 231 and the second capacitor electrode 232 of each sub-capacitor Sc may include a conductive material.

Each of the sub-capacitor Sc may be formed by using a process of forming the second thin film transistor TR2. For example, the first capacitor electrode 231 may be disposed on a same layer as the gate connection line 223c, and the second capacitor electrode 232 may be disposed on a same layer as the source connection line 227c. The first capacitor electrode 231 may include a same material as the gate connection line 223c, and the second capacitor electrode 232 may include a same material as the source connection line 227c. The first capacitor electrode 231 may be formed by a same process as the gate connection line 223c, and the second capacitor electrode 232 may be formed by a same process as the source connection line 227c. For example, the first capacitor electrode 231 may be formed simultaneously with the gate connection line 223c, and the second capacitor electrode 232 may be formed simultaneously with the source connection line 227c. Thus, in the display apparatus according to the example embodiment of the present disclosure, the decrease of the process efficiency due to a process of forming the storage capacitor Cst may be prevented.

The first capacitor electrode 231 of each sub-capacitor Sc may be directly connected to the gate connection line 223c. Each of the sub-capacitors Sc may be surrounded by one of the second drain electrodes 225 and one of the second source electrodes 227. For example, the second capacitor electrode 232 of some of the sub-capacitors Sc may be directly connected to the source connection line 227c, and the second capacitor electrode 232 of the remaining sub-capacitors Sc may be connected to the source connection line 227c through an auxiliary connection line 250.

The auxiliary connection line 250 may include a conductive material. For example, the auxiliary connection line 250 may include a metal, such as aluminum (Al), chrome (Cr), copper (Cu), molybdenum (Mo), titanium (Ti) and tungsten (W). The auxiliary connection line 250 may be disposed on a different layer than the gate connection line 223c and the source connection line 227c. For example, the auxiliary connection line 250 may include a different material from the gate connection line 223c and the source connection line 227c.

The sub-capacitors Sc may be individually connected to the gate connection line 223c and the source connection line 227c. Thus, in the display apparatus according to the example embodiment of the present disclosure, when a defect occurs in some of the sub-capacitors Sc, a region between the corresponding sub-capacitor Sc and the gate connection line 223c and a region between the corresponding sub-capacitor Sc and the source connection line 227c may be removed, so that the corresponding sub-capacitor Sc may be electrically insulated from the gate connection line 223c and the source connection line 227c. For example, in the display apparatus according to the example embodiment of the present disclosure, the storage capacitor Cst may be repaired by a process of removing a portion of the auxiliary connection line 250 and a portion of the second capacitor electrode 232 of the sub-capacitor Sc in which the defect occurs, using a laser. That is, in the display apparatus according to the example embodiment of the present disclosure, even if a defect occurs in some of the sub-capacitors Sc due to a conductive foreign material or an electrostatic short, a voltage applied to the first node N1 by the storage capacitor Cst may be maintained for one frame. Therefore, in the display apparatus according to the example embodiment of the present disclosure, the reliability of the driving circuit DC in each pixel area PA may be improved.

The driving circuit DC and the display device 300 of each pixel area PA may be supported by a device substrate 100. For example, the driving circuit DC and the display device 300 of each pixel area PA may be disposed on the device substrate 100. The device substrate 100 may include an insulating material. For example, the device substrate 100 may include glass or plastic.

A plurality of insulating layers 110, 120, 130, 140, 150 and 160 for preventing unnecessary electrical connection may be disposed on the device substrate 100. For example, a buffer insulating layer 110, a gate insulating layer 120, an interlayer insulating layer 130, a device passivation layer 140, a planarization layer 150 and a bank insulating layer 160 may be disposed on the device substrate 100.

The buffer insulating layer 110 may be disposed close to the device substrate 100. The buffer insulating layer 110 may prevent pollution due to the device substrate 100 in a process of forming the first semiconductor pattern, the second semiconductor patterns 221 and the third semiconductor pattern of each pixel area PA. For example, an upper surface of the device substrate 100 toward the first semiconductor pattern, the second semiconductor patterns 221 and the third semiconductor pattern of each pixel area PA may be completely covered by the buffer insulating layer 110. The first semiconductor pattern, the second semiconductor patterns 221 and the third semiconductor pattern of each pixel area PA may be disposed on the buffer insulating layer 110. The buffer insulating layer 110 may include an insulating material. For example, the buffer insulating layer 110 may include an inorganic insulating material, such as silicon oxide (SiOx) and silicon nitride (SiNx). The buffer insulating layer 110 may include a multi-layer structure. For example, the buffer insulating layer 110 may have a stacked structure of an inorganic insulating layer made of silicon oxide (SiOx) and an inorganic insulating layer made of silicon nitride (SiNx).

Light-blocking patterns 105 may be disposed between the device substrate 100 and the buffer insulating layer 110 of each pixel area PA. The light-blocking pattern 105 of each pixel area PA may include a material capable of absorbing or blocking light. For example, the light-blocking pattern 105 of each pixel area PA may include a metal, such as aluminum (Al), chrome (Cr), copper (Cu), molybdenum (Mo), titanium (Ti) and tungsten (W). The light travelling in a direction of the second semiconductor patterns 221 of each pixel area PA though the device substrate 100 may be blocked by one of the light-blocking patterns 105 in the corresponding pixel area PA. Thus, in the display apparatus according to the example embodiment of the present disclosure, changes in the characteristics of the second thin film transistor TR2 in each pixel area PA due to the external light may be prevented.

The first capacitor electrode 231 of each sub-capacitor Sc in each pixel area PA may be disposed between the device substrate 100 and the buffer insulating layer 110. For example, the light-blocking patterns 105 of each pixel area PA may be disposed on a same layer as the gate connection line 223c and the first capacitor electrodes 231 of the corresponding pixel area PA. The light-blocking patterns 105, the gate connection line 223c and the first capacitor electrodes 231 of each pixel area PA may be covered by the buffer insulating layer 110. For example, the light-blocking patterns 105, the gate connection line 223c and the first capacitor electrodes 231 of each pixel area PA may be in direct contact with the upper surface of the device substrate 100. The light-blocking patterns 105 of each pixel area PA may include a same material as the gate connection line 223c and the first capacitor electrodes 231 of the corresponding pixel area PA. The light-blocking patterns 105 of each pixel area PA may be formed by a same process as the gate connection line 223c and the first capacitor electrodes 231 of the corresponding pixel area PA. For example, the light-blocking patterns 105 of each pixel area PA may be formed simultaneously with the gate connection line 223c and the first capacitor electrodes 231 of the corresponding pixel area PA.

Each of the light-blocking patterns 105 may extend in the second direction Y. Each of the light-blocking patterns 105 may be spaced apart from the light-blocking pattern 105 adjacent in the first direction X. For example, the second semiconductor patterns 221 disposed side by side in the second direction within each pixel area PA may overlap one of the light-blocking patterns 105 in the corresponding pixel area PA. A specific voltage may be applied to each light-blocking pattern 105. For example, each of the light-blocking patterns 105 in each pixel area PA may be electrically connected to the source connection line 227c. Thus, in the display apparatus according to the example embodiment of the present disclosure, changes in the characteristics of the second thin film transistor TR2 in each pixel area PA due to the external light may be effectively prevented. The light-blocking patterns 105 of each pixel area PA may be spaced apart from the gate connection line 223c and the first capacitor electrodes 231 of the corresponding pixel area PA. For example, each of the light-blocking patterns 105 in each pixel area PA may be disposed between the first capacitor electrodes 231 of the corresponding pixel area PA. The light-blocking patterns 105 and the first capacitor electrodes 231 of each pixel area PA may be alternately disposed in the first direction X.

The gate insulating layer 120 may be disposed on the buffer insulating layer 110. The first gate electrode of each pixel area PA may be insulated from the first semiconductor pattern of the corresponding pixel area PA by the gate insulating layer 120. The second gate electrodes 223 of each pixel area PA may be insulated from the second semiconductor patterns 221 of the corresponding pixel area PA by the gate insulating layer 120. The third gate electrode of each pixel area PA may be insulated from the third semiconductor patterns of the corresponding pixel area PA by the gate insulating layer 120. For example, the gate insulating layer 120 may cover the first semiconductor pattern, the second semiconductor patterns 221 and the third semiconductor pattern of each pixel area PA. The first gate electrode, the second gate electrodes 223, the second drain electrodes 225, the second source electrodes 227 and the third gate electrode of each pixel area PA may be disposed on the gate insulating layer 120. The gate insulating layer 120 may include an insulating material. For example, the gate insulating layer 120 may include an inorganic insulating material.

The interlayer insulating layer 130 may be disposed on the gate insulating layer 120. The interlayer insulating layer 130 may include an insulating material. For example, the interlayer insulating layer 130 may be an inorganic insulating material.

The drain connection line 225c and the source connection line 227c of each pixel area PA may be disposed on a same layer as the second gate electrodes 223, the second drain electrodes 225 and the second source electrodes 227 of the corresponding pixel area PA. For example, the drain connection line 225c and the source connection line 227c of each pixel area PA may be disposed between the gate insulating layer 120 and the interlayer insulating layer 130 of the corresponding pixel area PA. The interlayer insulating layer 130 may cover the drain connection line 225c and the source connection line 227c of each pixel area PA. The first drain electrode, the first source electrode, the third drain electrode and the third source electrode of each pixel area PA may be disposed on a different layer than the second drain electrodes 225 and the second source electrodes 227 of the corresponding pixel area PA. For example, the first drain electrode, the first source electrode, the third drain electrode and the third source electrode of each pixel area PA may be disposed on the interlayer insulating layer 130. The interlayer insulating layer 130 may cover the first gate electrode, the second gate electrodes 223, the second drain electrodes 225, the second source electrodes 227 and the third gate electrode of each pixel area PA. The first drain electrode and the first source electrode of each pixel area PA may be insulated from the first gate electrode of the corresponding pixel area PA by the gate insulating layer 120 and the interlayer insulating layer 130. The third drain electrode and the third source electrode of each pixel area PA may be insulating from the third gate electrode of the corresponding pixel area PA by the gate insulating layer 120 and the interlayer insulating layer 130. Each of the second drain electrodes 225 may be in direct contact with the second drain region of the corresponding second semiconductor pattern 221 by penetrating the gate insulating layer 120. Each of the second source electrodes 227 may be in direct contact with the second source region of the corresponding second semiconductor pattern 221 by penetrating the gate insulating layer 120.

The auxiliary connection line 250 of each pixel area PA may be disposed on a same layer as the first drain electrode, the first source electrode, the third drain electrode and the third source electrode of the corresponding pixel area PA. For example, the auxiliary connection line 250 of each pixel area PA may be disposed on the interlayer insulating layer 130. The auxiliary connection line 250 of each pixel area PA may include a same material as the first drain electrode, the first source electrode, the third drain electrode and the third source electrode of the corresponding pixel area PA. The auxiliary connection line 250 of each pixel area PA may be formed by a same process as the first drain electrode, the first source electrode, the third drain electrode and the third source electrode of the corresponding pixel area PA. For example, the auxiliary connection line 250 of each pixel area PA may be formed simultaneously with the first drain electrode, the first source electrode, the third drain electrode and the third source electrode of the corresponding pixel area PA. The auxiliary connection line 250 of each pixel area PA may be in direct contact with the source connection line 227c and the second capacitor electrode 232 of some of the sub-capacitors Sc in the corresponding pixel area PA.

The device passivation layer 140 may be disposed on the interlayer insulating layer 130. The device passivation layer 140 may prevent damage of the driving circuit DC in each pixel area PA due to external impact and moisture. For example, the driving circuit DC of each pixel area PA may be covered by the device passivation layer 140. The device passivation layer 140 may cover the first drain electrode, the first source electrode, the third drain electrode and the third source electrode of each pixel area PA. The auxiliary connection line 250 of each pixel area PA may be covered by the device passivation layer 140. The device passivation layer 140 may include an insulating material. For example, the device passivation layer 140 may be an inorganic insulating layer made of an inorganic insulating material.

The planarization layer 150 may be disposed on the device passivation layer 140. The planarization layer 150 may remove a thickness difference due to the driving circuit DC of each pixel area PA. For example, an upper surface of the planarization layer 150 opposite to the device substrate 100 may be a flat surface. The upper surface of the planarization layer 150 may be parallel to the upper surface of the device substrate 100. The planarization layer 150 may include an insulating material. The planarization layer 150 may include a material different from the device passivation layer 140. The planarization layer 150 may include a material having relative high fluidity. For example, the planarization layer 150 may include an organic insulating material.

The display device 300 of each pixel area PA may be disposed on the planarization layer 150. The display device 300 of each pixel area PA may emit light displaying a specific color. For example, the display device 300 of each pixel area PA may include a first electrode 310, a light-emitting unit 320 and a second electrode 330, which are sequentially stacked on the planarization layer 150 of the corresponding pixel area PA.

The first electrode 310 may include a conductive material. The first electrode 310 may include a material having a high reflectance. For example, the first electrode 310 may include a metal, such as aluminum (Al) or silver (Ag). The first electrode 310 may have a multi-layer structure. For example, the first electrode 310 may have a structure in which a reflective electrode made of a metal is disposed between transparent electrodes made of a transparent conductive material, such as ITO and IZO.

The light-emitting unit 320 may generate light having luminance corresponding to a voltage difference between the first electrode 310 and the second electrode 330. For example, the light-emitting unit 320 may include an emission material layer (EML). The emission material layer may include an emission material. The emission material may include an organic material, an inorganic material, or a hybrid material. For example, the display apparatus according to the example embodiment of the present disclosure may be an organic light-emitting display apparatus including an organic emission material.

A plurality of emission material layers EML may be disposed in the light-emitting unit 320. For example, the light-emitting unit 320 may include a plurality of emission stacks having at least one emission material layer and at least one charge generation layer between the emission stacks. The charge generation layer may supply holes or electrons to adjacent emissions stack. Thus, in the display apparatus according to the example embodiment of the present disclosure, each of the emission stacks may emit light. The light emitted from each emission stack may display a same color. Therefore, in the display apparatus according to the example embodiment of the present disclosure, color reproduction may be improved.

The light-emitting unit 320 may include at least one functional layer. The functional layer may be one of a hole injection layer (HIL), a hole transport layer (HTL), an electron transport layer (ETL) and an electron injection layer (EIL). Thus, in the display apparatus according to the example embodiment of the present disclosure, efficiency of the light-emitting unit 320 may be improved.

The second electrode 330 may include a conductive material. The second electrode 330 may include a different material from the first electrode 310. A transmittance of the second electrode 330 may be higher than a transmittance of the first electrode 310. For example, the second electrode 330 may be a transparent electrode made of a transparent conductive material, such as ITO and IZO, or a translucent electrode in which metals such as Ag and Mg are thinly formed. Thus, in the display apparatus according to the example embodiment of the present disclosure, light generated by the light-emitting unit 320 may be emitted outside through the second electrode 330.

The display device 300 of each pixel area PA may be electrically connected to the second thin film transistor TR2 of the driving circuit DC in the corresponding pixel area PA. The first electrode 310 of each pixel area PA may be electrically connected to the third node N3 of the corresponding pixel area PA. The first electrode 310 of each pixel area PA may include a portion overlapping with the source connection line 227c of the corresponding pixel area PA. For example, the first electrode 310 of each pixel area PA may be in direct contact with the source connection line 227c of the corresponding pixel area PA by penetrating the planarization layer 150. The first electrode 310 of each pixel area PA may include a region directly contacting the upper surface of the planarization layer 150. For example, the light-emitting unit 320 and the second electrode 330 of each pixel area PA may be stacked on a portion of the corresponding first electrode 310 directly contacting the upper surface of the planarization layer 150.

The bank insulating layer 160 may be disposed on the planarization layer 150. The bank insulating layer 160 may include an insulating material. For example, the bank insulating layer 160 may include an organic insulating material. The bank insulating layer 160 may include a different material from the planarization layer 150.

The bank insulating layer 160 may define an emission area in each pixel area PA. The first electrode 310 of each pixel area PA may be partially exposed by the bank insulating layer 160. For example, an edge of the first electrode 310 in each pixel area PA may be covered by the bank insulating layer 160. Thus, in the display apparatus according to the example embodiment of the present disclosure, the first electrode 310 of each pixel area PA may be insulated from the first electrode 310 of adjacent pixel area PA by the bank insulating layer 160.

A portion of the first electrode 310 in each pixel area PA exposed by the bank insulating layer 160 may overlap the emission area of the corresponding pixel area PA. The portion of the first electrode 310 in each pixel area PA overlapping with the emission area of the corresponding pixel area PA may be in direct contact with the upper surface of the planarization layer 150. That is, in the display apparatus according to the example embodiment of the present disclosure, the light-emitting unit 320 and the second electrode 330 of each pixel area PA may be stacked on the emission area of the corresponding pixel area PA defined by the bank insulating layer 160. Thus, in the display apparatus according to the example embodiment of the present disclosure, luminance deviation according to the generating location of the light emitted from each pixel area PA may be prevented.

A voltage applied to the second electrode 330 of each pixel area PA may be a same as a voltage applied to the second electrode 330 of adjacent pixel area PA. For example, the second electrode 330 of each pixel area PA may be electrically connected to the second electrode 330 of adjacent pixel area PA. The second electrode 330 of each pixel area PA may include a same material as the second electrode 330 of adjacent pixel area PA. The second electrode 330 of each pixel area PA may be formed of a same process as the second electrode 330 of adjacent pixel area PA. For example, the second electrode 330 of each pixel area PA may be formed simultaneously with the second electrode 330 of adjacent pixel area PA. The second electrode 330 of each pixel area PA may be in direct contact with the second electrode 330 of adjacent pixel area PA. For example, the second electrode 330 of each pixel area PA may extend onto the bank insulating layer 160. Thus, in the display apparatus according to the example embodiment of the present disclosure, a process of forming the second electrode 330 in each pixel area PA may be simplified. And, in the display apparatus according to the example embodiment of the present disclosure, the luminance of the light emitted from the light-emitting unit 320 of each pixel area PA may be adjusted by the data signal applied to the driving circuit DC of the corresponding pixel area PA.

The image realized by the pixel areas PA may include various colors. The light emitted from the display device 300 of each pixel area PA may display a different color from the light emitted from the display device 300 of adjacent pixel area PA. For example, each of the pixel areas PA may include one of a red pixel area in which the light emitted from the display device 300 displays red color, a blue pixel area in which the light emitted from the display device 300 displays blue color, and a green pixel area in which the light emitted from the display device 300 displays green color. Some of the light-emitting unit 320 of each pixel area PA may be spaced apart from the light-emitting unit 320 of adjacent pixel area PA. For example, the emission material layer (EML) of each pixel area PA may be spaced apart from the emission material layer (EML) of adjacent pixel area PA. The light-emitting unit 320 of each pixel area PA may include an end on the bank insulating layer 160.

An encapsulation structure 400 may be disposed on the display device 300 of each pixel area PA. The encapsulation structure 400 may prevent damage of the display devices 300 due to the external moisture and impact. The encapsulation structure 400 may have a multi-layer structure. For example, the encapsulation structure 400 may have a stacked structure of a first encapsulating layer 410, a second encapsulating layer 420 and a third encapsulating layer 430. The first encapsulating layer 410, the second encapsulating layer 420 and the third encapsulating layer 430 may include an insulating material. The second encapsulating layer 420 may include a different material from the first encapsulating layer 410 and the third encapsulating layer 430. For example, the first encapsulating layer 410 and the third encapsulating layer 430 may include an inorganic insulating material, and the second encapsulating layer 420 may include an organic insulating material. Thus, in the display apparatus according to the example embodiment of the present disclosure, the damage of the display devices 300 due to the external moisture and impact may be effectively prevented. A thickness difference due to the display device 300 of each pixel area PA may be removed by the second encapsulating layer 420. A thickness of the second encapsulating layer 420 may be greater than a thickness of the first encapsulating layer 410 and a thickness of the third encapsulating layer 430. For example, an upper surface of the encapsulation structure 400 opposite to the device substrate 100 may be a flat surface. The upper surface of the encapsulation structure 400 may be parallel to the upper surface of the device substrate 100.

Accordingly, the display apparatus according to the example embodiment of the present disclosure may include the display device 300 and the driving circuit DC electrically connected to the display device 300 in each pixel area PA, wherein the second thin film transistor TR2 of the driving circuit DC which functions as a driving thin film transistor may consist of the plurality of sub-transistors St disposed side by side in the first direction X and the second direction Y, wherein the storage capacitor Cst of the driving circuit DC may include the plurality of sub-capacitors Sc disposed between the sub-transistors St spaced apart in the first direction X. Thus, in the display apparatus according to the example embodiment of the present disclosure, deterioration and/or damage of the second thin film transistor TR2 in each pixel area PA due to the heat generated by the operation of the driving circuit DC in the corresponding pixel area PA may be prevented, without increasing the total size. Therefore, in the display apparatus according to the example embodiment of the present disclosure, when driven at high current, the reliability of the driving circuit DC may be improved.

And, in the display apparatus according to the example embodiment of the present disclosure, a process of separating a portion of the second thin film transistor TR2 and/or a portion of the storage capacitor Cst in each pixel area PA may be simplified. That is, in the display apparatus according to the example embodiment of the present disclosure, even if the second thin film transistor TR2 and/or the storage capacitor Cst of each pixel area PA are partially damaged due to a conductive foreign material or an electrostatic short, the driving circuit DC of the corresponding pixel area PA may be normally driven. Therefore, in the display apparatus according to the example embodiment of the present disclosure, the efficiency and the reliability of the driving circuit DC in each pixel area PA may be increased.

The display apparatus according to the example embodiment of the present disclosure is described that the driving circuit DC of each pixel area PA is composed of the first thin film transistor TR1, the second thin film transistor TR2, the third thin film transistor TR3 and the storage capacitor Cst. However, in the display apparatus according to another example embodiment of the present disclosure, the driving circuit DC of each pixel area PA may include a driving thin film transistor and at least one switching thin film transistor. For example, in the display apparatus according to another example embodiment of the present disclosure, the driving circuit DC of each pixel area PA may not include the third thin film transistor TR3. Thus, in the display apparatus according to another example embodiment of the present disclosure, the degree of freedom for configuration of the driving circuit DC in each pixel area PA may be improved.

In the display apparatus according to the example embodiment of the present disclosure, the position and the electrical connection of the first drain electrode, the first source electrode, the second drain electrodes 225, the second source electrodes 227, the third drain electrode and the third source electrode in each pixel area PA may vary depending on the configuration of the corresponding driving circuit DC and/or the type of the corresponding thin film transistors TR1, TR2 and TR3. For example, in the display apparatus according to another example embodiment of the present disclosure, the second gate connection line 223c of each pixel area PA may be electrically connected to the first drain electrode of the corresponding pixel area PA through the first node N1 of the corresponding pixel area PA. Thus, in the display apparatus according to another example embodiment of the present disclosure, the degree of freedom for the configuration of each driving circuit DC and the type of each thin film transistors TR1, TR2 and TR3 may be improved.

The display apparatus according to the example embodiment of the present disclosure is described that the second drain electrodes 225 and the second source electrodes 227 of each pixel area PA may be disposed on a same layer as the second gate electrodes 223 of the corresponding pixel area PA. However, in the display apparatus according to another example embodiment of the present disclosure, the second drain electrodes 225 and the second source electrodes 227 of each pixel area PA may be disposed on a same layer as the first drain electrode, the first source electrode, the third drain electrode and the third source electrode of the corresponding pixel area PA. For example, in the display apparatus according to another example embodiment of the present disclosure, the second drain electrodes 225 and the second source electrodes 227 of each pixel area PA may be disposed between the interlayer insulating layer 130 and the device passivation layer 140 of the corresponding pixel area PA. Thus, in the display apparatus according to another example embodiment of the present disclosure, the degree of freedom for the configuration of the second thin film transistor TR2 in each pixel area PA may be improved.

In the display apparatus according to the example embodiment of the present disclosure, the second drain region of each second semiconductor pattern 221 in each pixel area PA may be electrically connected to the corresponding second drain electrode 225 through a plurality of contact holes, and the second source region of each second semiconductor pattern 221 may be electrically connected to the corresponding second source electrode 227 through a plurality of contact holes. Thus, in the display apparatus according to the example embodiment of the present disclosure, an electric connection between the second drain region of each second semiconductor pattern 221 and the corresponding second drain electrode 225 and an electric connection between the second source region of each second semiconductor pattern 221 and the corresponding second source electrode 227 may be stably maintained. That is, in the display apparatus according to the example embodiment of the present disclosure, the sub-transistors St in each pixel area PA may be stably driven. Therefore, in the display apparatus according to the example embodiment of the present disclosure, the efficiency and the reliability of the driving circuit DC in each pixel area PA may be improved.

The display apparatus according to another example embodiment of the present disclosure may include color filters disposed on a path of the light emitted from the display device 300 of each pixel area PA. For example, in the display apparatus according to another example embodiment of the present disclosure, the color filters may be disposed on the encapsulation structure 400. The light passing through the color filter on each pixel area PA may display a same color as the light emitted from the display device 300 of the corresponding pixel area PA. Thus, in the display apparatus according to another example embodiment of the present disclosure, the color reproduction may be improved.

The display device according to the example embodiment of the present disclosure is described that the light emitted from the display device 300 of each pixel area PA may display a different color from the light emitted from display device 300 of adjacent pixel area PA. However, in the display apparatus according to another example embodiment of the present disclosure, the light emitted from the display device 300 of each pixel area PA may display a same color as the light emitted from display device 300 of adjacent pixel area PA. For example, in the display apparatus according to another example embodiment of the present disclosure, the display device 300 of each pixel area PA may emit white light. That is, in the display apparatus according to another example embodiment of the present disclosure, the image having various colors may be realized by the color filters disposed in the pixel areas PA. Thus, in the display apparatus according to another example embodiment of the present disclosure, the light-emitting unit 320 of each pixel area PA may have a stacked structure same as the light-emitting unit 320 of adjacent pixel area PA. The light-emitting unit 320 of each pixel area PA may be formed by a same process as the light-emitting unit 320 of adjacent pixel area PA. For example, the light-emitting unit 320 of each pixel area PA may be formed simultaneously with the light-emitting unit 320 of adjacent pixel area PA. Therefore, in the display apparatus according to another example embodiment of the present disclosure, a process of forming the light-emitting unit 320 in each pixel area PA may be simplified.

The display device according to the example embodiment of the present disclosure is described that the display device 300 of each pixel area PA may be a self-luminous device in which at least one light emitting material layer (EML) is disposed between the first electrode 310 and the second electrode 330. However, in the display apparatus according to another example embodiment of the present disclosure, the display device 300 of each pixel area PA may have various configurations. For example, in the display apparatus according to another example embodiment of the present disclosure, the display device 300 of each pixel area PA may be a mini LED or micro LED using PN junction. Thus, in the display apparatus according to another example embodiment of the present disclosure, the degree of freedom for the display device 300 in each pixel area PA may be improved.

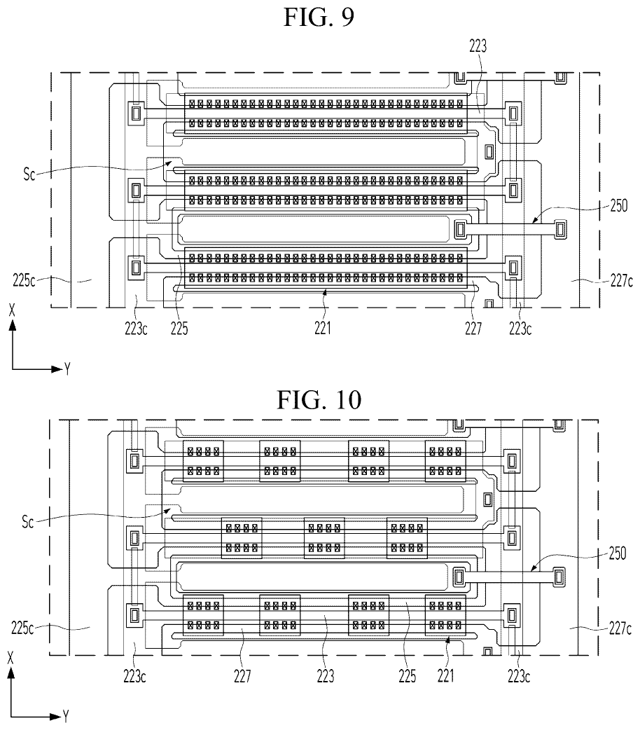

The display apparatus according to the example embodiment of the present disclosure is described that the second semiconductor patterns 221 in each pixel area PA may be spaced apart from each other. However, in the display apparatus according to another example embodiment of the present disclosure, the second semiconductor patterns 221 of each pixel area PA may have various shapes. For example, in the display apparatus according to another example embodiment of the present disclosure, each of the second semiconductor patterns 221 in each pixel area may extend in the second direction Y, as show in FIG. 9. Each of the second semiconductor pattern 221 in each pixel area PA may be spaced apart from the second semiconductor pattern 221 of the corresponding pixel area PA adjacent in the first direction X. Each of the sub-capacitors Sc in each pixel area may be disposed between the second semiconductor patterns 221 spaced apart in the first direction X. For example, the second semiconductor patterns 221 and the sub-capacitors Sc of each pixel area may extend in parallel in the second direction. Thus, in the display apparatus according to another example embodiment of the present disclosure, the degree of freedom for the shape of each second semiconductor pattern 221 may be improved.

The display apparatus according to the example embodiment of the present disclosure is described that arrangement of the second semiconductor patterns 221 in each pixel area PA may have a matrix shape. However, in the display apparatus according to another example embodiment of the present disclosure, the second semiconductor patterns 221 in each pixel area PA may be arranged in various shapes. For example, in the display apparatus according to another example embodiment of the present disclosure, each of the second semiconductor pattern 221 in each pixel area PA may be disposed alternately in the first direction X with the second semiconductor pattern 221 adjacent in the second direction Y, as shown in FIG. 10. Thus, in the display apparatus according to another example embodiment of the present disclosure, a distance between the second semiconductor patterns 221 in each pixel area PA may be increased. That is, in the display apparatus according to another example embodiment of the present disclosure, the heat generated by the operation of the driving circuit in each pixel area may be rapidly dissipated more quickly. Therefore, in the display apparatus according to another example embodiment of the present disclosure, when driven at high current, the reliability of the driving circuit in each pixel area PA may be effectively improved.

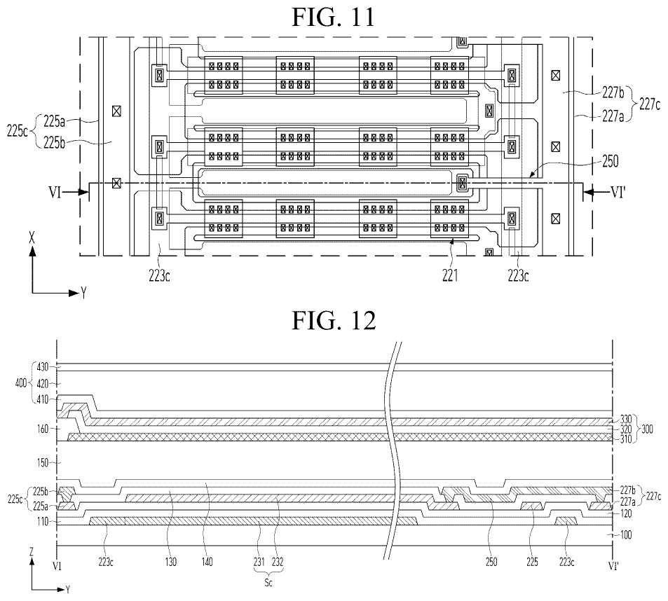

The display apparatus according to the example embodiment of the present disclosure is described that the drain connection line 225c and the source connection line 227c of each pixel area PA may have a single-layer structure. However, in the display apparatus according to another example embodiment of the present disclosure, the drain connection line 225c and the source connection line 227c of each pixel area PA may have a multi-layer structure. For example, in the display apparatus according to another example embodiment of the present disclosure, the drain connection line 225c of each pixel area PA may have a stacked structure of a first drain connecting layer 225a and a second drain connecting layer 225b, and the source connection line 227c of each pixel area PA may have a stacked structure of a first source connecting layer 227a and a second source connecting layer 227b, as shown in FIGS. 11 and 12.

The first source connecting layer 227a may be disposed on a same layer as the first drain connecting layer 225a. For example, the first drain connecting layer 225a and the first source connecting layer 227a may be disposed between the gate insulating layer 120 and the interlayer insulating layer 130. The second source connecting layer 227b may be disposed on a same layer as the second drain connecting layer 225b. The second drain connecting layer 225b may be disposed on a same layer as the auxiliary connection line 250. For example, the second drain connecting layer 225b and the second source connecting layer 227b may include a same material as the auxiliary connection line 250. The second drain connecting layer 225b and the second source connecting layer 227b may be formed by a same process as the auxiliary connection line 250. For example, the second drain connecting layer 225b and the second source connecting layer 227b may be formed simultaneously with the auxiliary connection line 250. The auxiliary connection line 250 may be in direct contact with the second source connecting layer 227b.

The second drain connecting layer 225b may be electrically connected to the first drain connecting layer 225a. For example, the first drain connecting layer 225a and the second drain connecting layer 225b may extend in parallel in the first direction X. The second source connecting layer 227b may be electrically connected to the first source connecting layer 227a. For example, the first source connecting layer 227a and the second source connecting layer 227b may extend in parallel in the first direction X. Thus, in the display apparatus according to another example embodiment of the present disclosure, a resistance of the drain connection line 225c and a resistance of the source connection line 227c in each pixel area may be reduced. That is, in the display apparatus according to another example embodiment of the present disclosure, a signal delay according to the location of each second semiconductor pattern 221 in each pixel area may be reduced or prevented. Therefore, in the display apparatus according to another example embodiment of the present disclosure, characteristics in the operation of the second thin film transistor in each pixel area may be improved. And, in the display apparatus according to another example embodiment of the present disclosure, the efficiency and the reliability of the driving circuit in each pixel area may be effectively improved.

In the result, the display apparatus according to the example embodiments of the present disclosure may comprise the display device electrically connected to the driving circuit, wherein the driving circuit may include the thin film transistor and the storage capacitor, wherein the thin film transistor may include the plurality of semiconductor patterns spaced apart in the first direction, wherein the storage capacitor may include the sub-capacitor disposed between the semiconductor patterns spaced apart in the first direction. Thus, in the display apparatus according to the example embodiments of the present disclosure, each of the semiconductor patterns may be sufficiently spaced apart from adjacent semiconductor pattern. That is, in the display apparatus according to the example embodiments of the present disclosure, the heat generated by the operation of the driving circuit may be rapidly dissipated through a space between the semiconductor patterns spaced apart in the first direction. Thereby, in the display apparatus according to the example embodiments of the present disclosure, the efficiency and the reliability of the driving circuit may be improved, when driven at high current. And, in the display apparatus according to the example embodiments of the present disclosure, low power driving may be possibly by improving the efficiency of the driving circuit, and power consumption may be reduced.

It will be apparent to those skilled in the art that various modifications and variations can be made in the present disclosure without departing from the technical idea or scope of the present disclosure. Thus, it is intended that the present disclosure covers the modifications and variations of this disclosure that come within the scope of the claims and their equivalents.

What is claimed is:

1. A display apparatus, comprising:
a driving circuit including a thin film transistor and a storage capacitor; and
a display device for being electrically connected to the driving circuit,
wherein the thin film transistor includes a plurality of sub-transistors connected in parallel,
wherein each of the plurality of sub-transistors includes a semiconductor pattern, a gate electrode, a drain electrode and a source electrode,
wherein the plurality of sub-transistors are arranged in a first direction; and
wherein the storage capacitor includes a sub-capacitor disposed between the plurality of sub-transistors, which are spaced apart from each other.

2. The display apparatus according to claim 1, wherein the semiconductor pattern of each sub-transistor is spaced apart from the semiconductor pattern of adjacent sub-transistor in the first direction, and
wherein the sub-capacitor is disposed between the semiconductor patterns which are spaced apart in the first direction.

3. The display apparatus according to claim 1, wherein the sub-capacitor includes first and second capacitor electrodes extending in a second direction perpendicular to the first direction.

4. The display apparatus according to claim 3, wherein each sub-transistor includes a plurality of semiconductor patterns spaced apart in the second direction,
wherein the plurality of semiconductor patterns of each sub-transistor have a plurality of drain regions connected to each other by the drain electrode of the corresponding sub-transistor and a plurality of source regions connected to each other by the source electrode of the corresponding sub-transistor.

5. The display apparatus according to claim 3, wherein the semiconductor pattern of each sub-transistor extends in the second direction.

6. The display apparatus according to claim 3, wherein the gate electrode, the drain electrode and the source electrode of each sub-transistor extend in the second direction.

7. The display apparatus according to claim 6, wherein the thin film transistor further includes a gate connection line, a drain connection line and a source connection line, which extend in the first direction,
wherein the gate electrodes of the plurality of sub-transistors are for being electrically connected to the gate connection line,
wherein the drain electrodes of the plurality of sub-transistors are for being electrically connected to the drain connection line, and
wherein the source electrodes of the plurality of sub-transistors are for being electrically connected to the source connection line.

8. The display apparatus according to claim 7, further comprising:
a device substrate supporting the driving circuit and the display device; and
light-blocking patterns disposed between the device substrate and the semiconductor pattern of each sub-transistor,
wherein the gate connection line is disposed on a same layer as the light-blocking patterns, and
wherein the drain connection line and the source connection line are disposed on a different layer than the gate connection line.

9. The display apparatus according to claim 7, wherein the semiconductor patterns of the plurality of sub-transistors is disposed between the drain connection line and the source connection line in the second direction.

10. The display apparatus according to claim 9, wherein the gate connection line extends between the drain connection line and the semiconductor patterns of the plurality of sub-transistors and extends between the semiconductor patterns of the plurality of sub-transistors and the source connection line.

11. The display apparatus according to claim 7, wherein the first capacitor electrode is electrically connected to the gate connection line and the second capacitor electrode is electrically connected to the source connection line.

12. The display apparatus according to claim 11, wherein the first capacitor electrode is disposed on a same layer as the gate connection line, and
wherein the second capacitor electrode is disposed on a same layer as the source connection line.

13. The display apparatus according to claim 8, wherein the light-blocking patterns are disposed alternately with the sub-capacitor in the first direction.

14. A display apparatus, comprising:
a thin film transistor disposed in a pixel area of a device substrate, the thin film transistor including a gate connection line, a drain connection line and a source connection line;
a display device which received a driving current from the thin film transistor; and
a storage capacitor disposed between the gate connection line and the source connection line of the thin film transistor,
wherein the thin film transistor includes a plurality of semiconductor patterns spaced apart in a first direction,
wherein the plurality of semiconductor patterns are disposed between the drain connection line and the source connection line spaced apart in a second direction perpendicular to the first direction, and
wherein the storage capacitor is disposed between the semiconductor patterns spaced apart in the first direction.

15. The display apparatus according to claim 14, wherein the plurality of semiconductor patterns are further spaced apart in the second direction.

16. The display apparatus according to claim 15, wherein each of the semiconductor patterns is arranged to be staggered in the second direction with the semiconductor pattern adjacent in the first direction.

17. The display apparatus according to claim 14, wherein the thin film transistor includes a plurality of gate electrodes for being electrically connected to the gate connection line, a plurality of drain electrodes for being electrically connected to the drain connection line, and a plurality of source electrodes for being electrically connected to the source connection line,
wherein each of the plurality of gate electrodes overlaps a channel region of at least one of the semiconductor patterns,
wherein each of the plurality of drain electrodes is for being electrically connected to a drain region of at least one of the semiconductor patterns, and
wherein each of the plurality of source electrodes is for being electrically connected to a source region of at least one of the semiconductor patterns.

18. The display apparatus according to claim 17, wherein the plurality of drain electrodes are disposed on a same layer as the drain connection line,
wherein the plurality of source electrodes are disposed on a same layer as the source connection line, and
wherein the plurality of gate electrodes are disposed on a different layer than the gate connection line.

19. The display apparatus according to claim 14, wherein the storage capacitor includes a first capacitor electrode electrically connected to the gate connection line and a second capacitor electrode electrically connected to the source connection line.

20. The display apparatus according to claim 19, wherein the source connection line is disposed on a different layer from the gate connection line,
wherein the first capacitor electrode is disposed on a same layer as the gate connection line, and
wherein the second capacitor electrode is disposed on a same layer as the source connection line.
